(19) United States
(12) Patent Application Publication
(10) Pub. No.: US 2024/0149295 A1
(43) Pub. Date: May 9, 2024

(54) Thin Film Coating Apparatus and Method for Use of Thin Film Coating Apparatus

(71) Applicant: King Khalid University, Abha (SA)

(72) Inventors: Abdullah G. Al-Sehemi, Abha (SA); H. Algarni, Abha (SA); Fahrettin Yakuphanoglu, Elazig (TR); Ahmed A. Al-Ghamdi, Jeddah (SA); Aysegul DERE, Elazig (TR); Mehboobali Pannipara, Abha (SA)

(21) Appl. No.: 18/053,867

(22) Filed: Nov. 9, 2022

(51) Int. Cl. B05D 1/00; B05C 9/14; B05C 11/10; B05C 13/02

(52) U.S. Cl. CPC B05D 1/005; B05C 9/14; B05C 11/1044; B05C 13/02

(57) ABSTRACT

A thin film coating apparatus is disclosed, including a sample holder rotatably configured in the apparatus. The sample holder is coupled to a motor configured to rotate the sample holder. The apparatus includes a heating chamber disposed around the sample holder. The heating chamber is configured to supply heat to a substrate loaded on the sample holder. The apparatus includes a top cover configured to selectively allow access to the substrate loaded on the sample holder. A controller is configured to: detect a speed of rotation of the sample holder; and operate the top cover to allow access to the substrate loaded on the sample holder when the detected speed of rotation of the sample holder is within a predefined range.

### TECHNICAL FIELD

The present disclosure generally relates to a thin film coater. In particular, the present disclosure relates to a thin film coater for making composite thin films.

### BACKGROUND

Background description includes information that may be useful in understanding the present invention. It is not an admission that any of the information provided herein is prior art or relevant to the presently claimed invention, or that any publication specifically or implicitly referenced is prior art.

One of common techniques used for preparing a thin film is by spin-coating. Spin coating is generally performed on an apparatus where a substrate is fixed on a rotating platform. A solution for the coating is dropped on the substrate, and the substrate is spun at a fixed speed for a specified duration of time for the solution to spread along the surface of the substrate.

However, the solution is introduced to on the substrate when the substrate is at rest, and then the substrate is rotated. The acceleration from rest to a certain speed may not be very uniform, resulting in a non-uniform film. Further, the temperature of the substrate may not be maintained at an optimum value, thereby resulting in uneven films.

There is, therefore, a requirement in the art for a means to provide a uniform, even thin film using a coating apparatus.

### OBJECTS OF INVENTION

An object of the present invention is to provide a coating apparatus for coating thin films on substrates.

An object of the present invention is to provide a coating apparatus that optimizes a coating process for preparing uniform thin films on substrates.

An object of the present invention is to provide a method for preparing uniform thin films on substrates.

### SUMMARY

The present disclosure generally relates to a thin film coater. In particular, the present disclosure relates to a thin film coater for making composite thin films.

In a first aspect, the present disclosure provides a thin film coating apparatus. The apparatus includes a sample holder rotatably configured in the thin film coating apparatus,
wherein the sample holder is coupled to a motor configured to rotate the sample holder. The apparatus further includes a heating chamber disposed around the sample holder, wherein the heating chamber is configured to supply heat to a substrate loaded on the sample holder. The apparatus further includes a top cover disposed on the heating chamber, the top cover configured to selectively allow access to the substrate loaded on the sample holder. The apparatus further includes a controller communicably coupled to the motor, the heating chamber, and the top cover, the controller including a processor communicably coupled to a memory storing instructions executable by the processor, the controller configured to: detect a speed of rotation of the sample holder. The controller is further configured to detect a temperature of the substrate loaded on the sample holder. The controller is further configured operate the top cover to allow access to the substrate loaded on the sample holder when the detected speed of rotation of the sample holder, and the detected temperature of the substrate loaded on the sample holder are within corresponding predefined ranges.

In some embodiments, the controller is further configured to operate the motor to vary the speed of rotation of the sample holder from the predefined range to a second value after a predefined duration of time.

In some embodiments, the apparatus further includes a vacuum chamber configured to apply a vacuum force at the sample holder to secure the substrate to the sample holder. The controller is configured to detect a presence of the substrate on the sample holder. The controller is further configured to operate the vacuum chamber to apply a vacuum force at the sample holder to secure the substrate to the sample holder on positive detection of the presence of the substrate on the sample holder.

In some embodiments, the apparatus further includes a touch screen device configured to at least one of display one or more operating parameters of the thin film coating apparatus and accept input relating to the one or more parameters of the thin film coating apparatus.

In some embodiments, the one or more operating parameters include at least one of a current speed of the sample holder, the predefined range for the speed of the sample holder, a temperature of the heating chamber, a state of the top cover, a duration of operation of the apparatus, and presence of the substrate loaded on the sample holder.

In some embodiments, the apparatus further includes a hot plate communicably coupled to the controller. The controller is configured to operate the hot plate to enable the hot plate to be maintained at a predefined temperature.

In some embodiments, the apparatus further includes a solution pourer adapted to store a solution to be dispensed on the substrate loaded on the sample holder. The solution pourer is communicably coupled to the controller. The controller is configured to operate the solution pourer to dispense a predefined quantity of the solution on the substrate loaded on the sample holder through the top cover.

In some embodiments, the solution pourer includes one or more syringes adapted to store the solution, wherein the syringes are actuated to dispense the predefined quantity of the solution by one or more actuators, and wherein the one or more actuators are operable by the controller.

In a second aspect, the present disclosure provides a method for use of the thin film coating apparatus of the first aspect. The method includes detecting, by the controller, the speed of rotation of the sample holder. The method further includes detecting, by the controller, the temperature of the substrate loaded on the sample holder. The method further includes operating, by the controller, the top cover to allow access to the substrate loaded on the sample holder when the detected speed of rotation of the sample holder, and the temperature of the substrate loaded on the sample holder are within corresponding predefined ranges.

In some embodiments, the method further includes varying, by the controller, the speed of rotation of the sample holder from the predefined range to a second value after a predefined duration of time.

Various objects, features, aspects, and advantages of the inventive subject matter will become more apparent from the following detailed description of preferred embodiments, along with the accompanying drawing figures in which like numerals represent like components.

### BRIEF DESCRIPTION OF DRAWINGS

The accompanying drawings are included to provide a further understanding of the present disclosure and are incorporated in and constitute a part of this specification. The drawings illustrate exemplary embodiments of the present disclosure and, together with the description, serve to explain the principles of the present disclosure.

FIG. 1 illustrates a schematic view of a thin film coating apparatus, according to an embodiment of the present disclosure;

FIG. 2 illustrates a schematic block diagram of a controller of the thin film coating apparatus of FIG. 1;

FIG. 3 illustrates a schematic flow diagram for a method to use the thin film coating apparatus of FIG. 1; and

FIG. 4 illustrates an exemplary block diagram of a computer system for implementing the controller of FIG. 2.

### DETAILED DESCRIPTION

The following is a detailed description of embodiments of the disclosure depicted in the accompanying drawings. The embodiments are in such details as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

In an aspect, the present disclosure provides a thin film coating apparatus. The apparatus includes a sample holder rotatably configured in the thin film coating apparatus, wherein the sample holder is coupled to a motor configured to rotate the sample holder. The apparatus further includes a heating chamber disposed around the sample holder, wherein the heating chamber is configured to supply heat to a substrate loaded on the sample holder. The apparatus further includes a top cover disposed on the heating chamber, the top cover configured to selectively allow access to the substrate loaded on the sample holder. The apparatus further includes a controller communicably coupled to the motor, the heating chamber, and the top cover, the controller including a processor communicably coupled to a memory storing instructions executable by the processor, the controller configured to: detect a speed of rotation of the sample holder. The controller is further configured to detect a temperature of the substrate loaded on the sample holder. The controller is further configured operate the top cover to allow access to the substrate loaded on the sample holder when the detected speed of rotation of the sample holder, and the detected temperature of the substrate loaded on the sample holder are within corresponding predefined ranges.

In some embodiments, the controller is further configured to operate the motor to vary the speed of rotation of the sample holder from the predefined range to a second value after a predefined duration of time.

In some embodiments, the apparatus further includes a vacuum chamber configured to apply a vacuum force at the sample holder to secure the substrate to the sample holder. The controller is configured to detect a presence of the substrate on the sample holder. The controller is further configured to operate the vacuum chamber to apply a vacuum force at the sample holder to secure the substrate to the sample holder on positive detection of the presence of the substrate on the sample holder.

In some embodiments, the apparatus further includes a touch screen device configured to at least one of display one or more operating parameters of the thin film coating apparatus and accept input relating to the one or more parameters of the thin film coating apparatus.

In some embodiments, the one or more operating parameters include at least one of a current speed of the sample holder, the predefined range for the speed of the sample holder, a temperature of the heating chamber, a state of the top cover, a duration of operation of the apparatus, and presence of the substrate loaded on the sample holder.

In some embodiments, the apparatus further includes a hot plate communicably coupled to the controller. The controller is configured to operate the hot plate to enable the hot plate to be maintained at a predefined temperature.

In some embodiments, the apparatus further includes a solution pourer adapted to store a solution to be dispensed on the substrate loaded on the sample holder. The solution pourer is communicably coupled to the controller. The controller is configured to operate the solution pourer to dispense a predefined quantity of the solution on the substrate loaded on the sample holder through the top cover.

In some embodiments, the solution pourer includes one or more syringes adapted to store the solution, wherein the syringes are actuated to dispense the predefined quantity of the solution by one or more actuators, and wherein the one or more actuators are operable by the controller.

In another aspect, the present disclosure provides a method for use of the thin film coating apparatus of the first aspect. The method includes detecting, by the controller, the speed of rotation of the sample holder. The method further includes detecting, by the controller, the temperature of the substrate loaded on the sample holder. The method further includes operating, by the controller, the top cover to allow access to the substrate loaded on the sample holder when the detected speed of rotation of the sample holder, and the temperature of the substrate loaded on the sample holder are within corresponding predefined ranges.

In some embodiments, the method further includes varying, by the controller, the speed of rotation of the sample holder from the predefined range to a second value after a predefined duration of time.

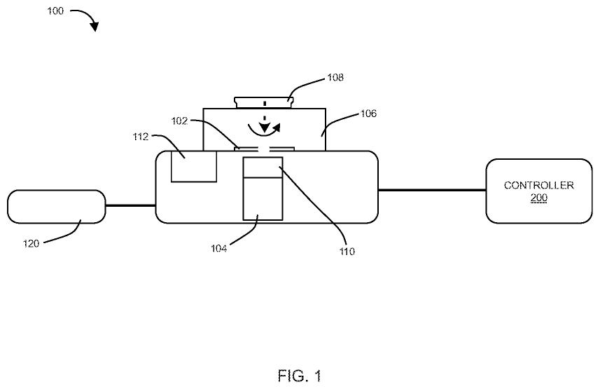

FIG. 1 illustrates a schematic view of a thin film coating apparatus 100, according to an embodiment of the present disclosure. The thin film coating apparatus 100 may interchangeably by referred to as “the apparatus 100”. The apparatus 100 includes a sample holder 102 rotatably configured in the apparatus 100. The sample holder 102 is configured to receive a substrate thereon. The substrate may be loaded on the sample holder 102 in order for the substrate to be coated. The sample holder 102 is coupled to a motor 104 that is configured to rotate the sample holder 102. The motor 104 may impart rotary motion to the sample holder 102, such that the sample holder 102 rotates along a horizontal plane.

In some embodiments, the motor 104 is any one of a DC and an AC motor. In some embodiments, the motor 104 is a multipolar motor. In some embodiments, the motor 104 is a six-pole motor. In some embodiments, the motor 104 may have a speed in range from about 100 RPM to about 15000 RPM. In some embodiments, the motor 104 may have a capacity for angular acceleration or deceleration at a rate of about 21 Rad/s². In some embodiments, the motor 104 may have a capacity for acceleration or deceleration at a rate of between about 1 RPM/s and about 40000 RPM/s. This allows the motor 104, and subsequently the sample holder 102 to reach a required speed quickly. In some embodiments, the motor 104 may include an electronic brake mechanism to enable the motor 104 to decelerate more evenly or uniformly.

The apparatus 100 further includes a heating chamber 106 disposed around the sample holder 102. The heating chamber 106 is configured to supply heat to the substrate loaded on the sample holder 102. Once a film solution is placed on the substrate loaded on the sample holder 102, the heat supplied by the heating chamber 106 may facilitate in solidification of the solution to form a film on the substrate. In some embodiments, the heating chamber 106 may use electromagnetic radiation to supply the heat. In some embodiments, the electromagnetic radiation may be infrared radiation. In some embodiments, the heating chamber 106 may be controlled used a PID (proportional integral derivative) method-based controller having a heating rate dT/dt.

The apparatus 100 further includes a top cover 108 disposed on the heating chamber 106. The top cover 108 is configured to selectively allow access to the sample holder 102.

In some embodiments, the apparatus 100 further includes a solution pourer (not shown in figure). The solution pourer may be operated to dispense a predefined quantity of the film solution on the substrate loaded on the sample holder 102. In some embodiments, the solution pourer includes one or more syringe pumps. The syringe pumps may store the film solution, and they may be actuated to dispense the predefined quantity of the solution. In some embodiments, the solution pourer may dispense discrete quantities of the film solution. In some other embodiments, the solution pourer may dispense the film solution at a predefined flow rate. The flow rate may be in the range of microliters/second, microlitres/minute, or microlitres/hour.

The apparatus 100 further includes a vacuum chamber 110. The vacuum chamber 110 may be located under the sample holder 102. The vacuum chamber 110 is configured to apply a vacuum pressure at the sample holder 102 in order to secure the substrate that is loaded on the sample holder 102.

The apparatus 100 further includes a touch screen device 112. The touch screed device 112 is configured to display one or more operating parameters of the apparatus 100. The one or more operating parameters includes at least one of a current speed of the sample holder 102, the predefined range for the speed of the sample holder 102, a temperature of the heating chamber 106, a state of the top cover 108, a duration of operation of the apparatus 100, and presence of the substrate loaded on the sample holder 102. The touch screen device 112 may also be configured to accept input pertaining to one or more operating parameters of the apparatus 100. In some examples, the input may be provided by a user of the apparatus 100.

The apparatus 100 further includes a hot plate 120. The hot plate 120 may be maintained at a predefined temperature and the substrate that has been spin-coated may be placed on the heated hot plate 120 to facilitate further solidification of the thin film.

The apparatus 100 further includes a controller 200 configured to operate the apparatus 100. The controller 200 is communicatively coupled to the different components of the apparatus 100, namely, the sample holder 102, the motor 104, the heating chamber 106, the top cover 108, the vacuum chamber 110, the touch screen device 112, and the hot plate 120.

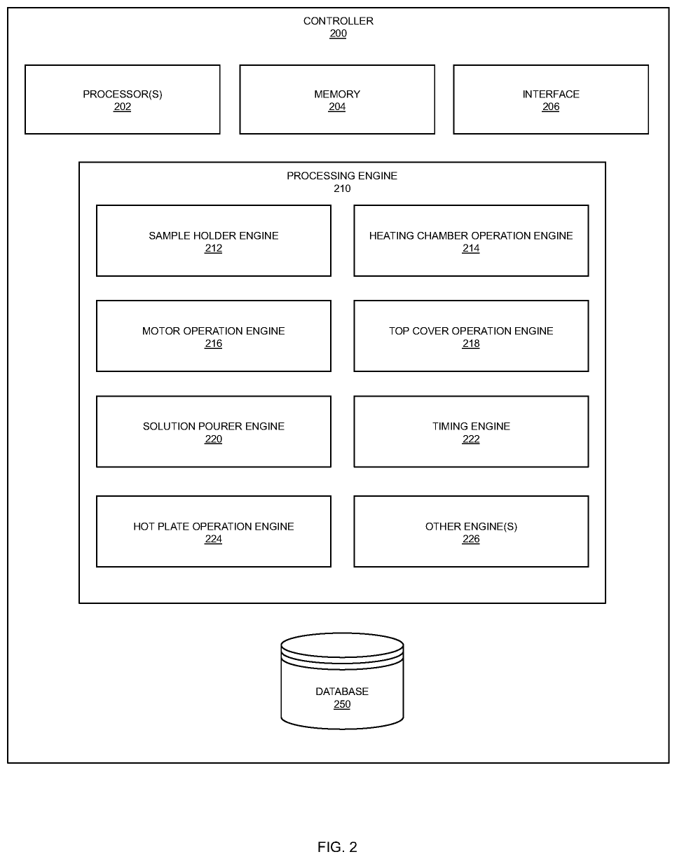

FIG. 2 illustrates a schematic block diagram of the controller 200, according to an embodiment of the present disclosure. Referring now to FIGS. 1 and 2, the controller 200 includes a processor 202 communicably coupled to a memory 204. The memory 204 stores instructions executable by the processor 202 to operate the apparatus 100. In some embodiments, the processor 202 may be implemented as one or more microprocessors, microcomputers, microcontrollers, digital signal processors, central processing units, logic circuitries, and/or any devices that process data based on operational instructions. Among other capabilities, the processor 202 may be configured to fetch and execute computer-readable instructions stored in the memory 204 for facilitating operation of the apparatus 100. Any reference to a task in the present disclosure may refer to an operation being or that may be performed on data. The memory 204 may be configured to store one or more computer-readable instructions or routines in a non-transitory computer readable storage medium for operating the apparatus 100. The memory 204 may include any non-transitory storage device including, for example, volatile memory such as RAM, or non-volatile memory such as EPROM, flash memory, and the like. In some embodiments, the controller 200 may include an interface 206. The interface 206 may include a variety of interfaces, for example, interfaces for data input and output devices, referred to as I/O devices, storage devices, and the like. The interface 206 may also provide a communication pathway for one or more components of the controller 200. Examples of such components include, but are not limited to, the processing engine 210 and a database 250.

In some embodiments, the controller 200 includes the processing engine 210. The processing engine 210 may be implemented as a combination of hardware and programming (for example, programmable instructions) to implement one or more functionalities of the processing engine 210. In examples described herein, such combinations of hardware and programming may be implemented in several different ways. For example, the programming for the processing engine 210 may be processor executable instructions stored on a non-transitory machine-readable storage medium and the hardware for the processing engine 210 may include a processing resource (for example, one or more processors), to execute such instructions. In the present examples, the machine-readable storage medium may store instructions that, when executed by the processing resource, implement the processing engine 210. In such examples, the controller 200 may include the machine-readable storage medium storing the instructions and the processing resource to execute the instructions, or the machine-readable storage medium may be separate but accessible to the controller 200 and the processing resource. In other examples, the processing engine 210 may be implemented by electronic circuitry.

The processing engine 210 includes a sample holder engine 212, a heating chamber operation engine 214, a motor operation engine 216, a top cover operation engine 218, a solution pourer engine 220, a timing engine 222, a hot plate engine 224, and other engines 226. The other engines 226 may include engines configured to perform one or more functions ancillary functions associated with the processing engine 210.

The sample holder engine 212 is configured to detect a presence of the substrate on the sample holder 102. On positive detection of the substrate on the sample holder 102, the sample holder engine 212 is further configured to operate the vacuum chamber 110 to secure the substrate to the sample holder 102. The sample holder engine 212 may be further configured to detect a current speed of rotation of the sample holder 102.

The heating chamber operation engine 214 is configured to operate the heating chamber 106 in order for the substrate to be maintained at a predefined temperature. The heating chamber operation engine 214 may be operable based on input received through the interface 206 regarding the predefined temperature that the is required to be maintained.

The motor operation engine 216 is configured to operate the motor 104 to effect rotation of the sample holder 102. The motor 104 is operated by supplying a current to the motor 104. The motor operation engine 216 is configured to regulate the current supplied to the motor 104, thereby regulating motor speed. The motor operation engine 216 is operable based on input received through the interface e206 regarding one or more speeds for the motor 104 to be rotated at so that the sample holder 102 correspondingly rotates at different speeds.

The top cover engine 218 is configured to operate the top cover 108 to selectively allow access to the substrate on the sample holder 102, once the heating chamber operation engine 214 and the motor operation engine 216 are operating. When the heating chamber 106 reaches a predefined temperature, and the motor 104 rotates at the predefined speed, the top cover engine 218 is configured to open, to allow the thin film solution to be dispensed onto the substrate.

The solution pourer engine 220 is configured to operate the solution pourer to dispense a predefined quantity of the thin film solution on the substrate.

The timing engine 222 is configured to detect a duration of operation of the apparatus 100. In some examples, the timing engine 222 may detect a duration of rotation of the sample holder 102. In some other examples, the timing engine 222 may detect a duration of rotation of the sample holder 102 at a certain speed of rotation.

The hot plate engine 224 is configured to operate the hot plate 120. The hot plate engine 224 may be operable based on input received through the interface 206 regarding the predefined temperature that the is required to be maintained by the hot plate 120.

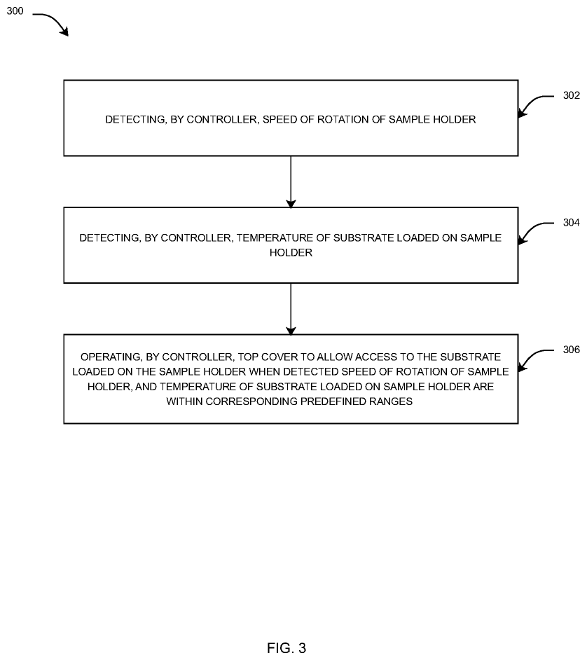

FIG. 3 illustrates a schematic flow diagram for a method 300 for use of the apparatus 100, according to an embodiment of the present disclosure. At step 302, the method 300 includes detecting, by the controller 200, the speed of rotation of the sample holder 102. At step 304, the method 300 further includes detecting, by the controller 200, the temperature of the substrate loaded on the sample holder 102. At step 306, the method 300 further includes operating, by the controller 200, the top cover 108 to allow access to the substrate loaded on the sample holder 102 when the detected speed of rotation of the sample holder 102, and the temperature of the substrate loaded on the sample holder 102 are within corresponding predefined ranges.

In some embodiments, the method 300 further includes varying, by the controller 200, the speed of rotation of the sample holder 102 from the predefined range to a second value after a predefined duration of time.

In some implementations, the apparatus 100 may be operated in three modes—static mode, dynamic mode, and multi-rpm mode.

In some embodiments, in the static mode, the solution from the solution pourer is dispensed when the sample holder 102 is rotating at zero speed, i.e., the sample holder 102 is at rest. The duration of operation of the apparatus 100 is detected after the sample holder 102 reaches a desired speed, and coating process occurs.

In some embodiments, in the dynamic mode, the sample holder 102 is allowed to reach a non-zero speed of rotation. The thin film solution is thereafter dispensed on the rotating substrate, and coating process occurs.

In some embodiments, in multi-rpm mode, the sample holder 102 is rotating initially at a first speed. The thin film solution is thereafter dispensed on the rotating substrate. After a first duration of time, the sample holder 102 speed is changed to a second speed, which is maintained for a second duration of time. The coating process occurs at different speeds.

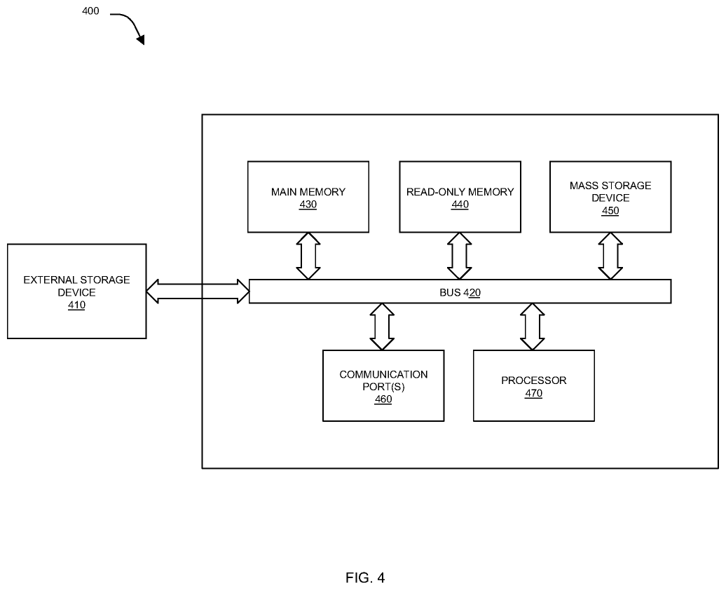

FIG. 4 illustrates an exemplary schematic block diagram of a hardware platform for implementation of the controller 200. As shown in FIG. 4, a computer system 400 can include an external storage device 410, a bus 420, a main memory 430, a read only memory 440, a mass storage device 450, communication port 460, and a processor 470. A person skilled in the art will appreciate that the computer system may include more than one processor and communication ports. Examples of processor 470 include, but are not limited to, an Intel® Itanium® or Itanium 2 processor(s), or AMD® Opteron® or Athlon MP® processor(s), Motorola® lines of processors, FortiSOC™ system on chip processors or other future processors. Processor 470 may include various modules associated with embodiments of the present invention. Communication port 460 can be any of an RS-232 port for use with a modem-based dialup connection, a 10/100 Ethernet port, a Gigabit or 10 Gigabit port using copper or fibre, a serial port, a parallel port, or other existing or future ports. Communication port 460 may be chosen depending on a network, such a Local Area Network (LAN), Wide Area Network (WAN), or any network to which computer system connects. Memory 430 can be Random Access Memory (RAM), or any other dynamic storage device commonly known in the art. Read-only memory 440 can be any static storage device(s) e.g., but not limited to, a Programmable Read Only Memory (PROM) chips for storing static information e.g., start-up or BIOS instructions for processor 470. Mass storage 450 may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 7102 family) or Hitachi (e.g., the Hitachi Deskstar 7K1000), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

Bus 420 communicatively couples processor(s) 470 with the other memory, storage, and communication blocks. Bus 420 can be, e.g., a Peripheral Component Interconnect (PCI)/PCI Extended (PCI-X) bus, Small Computer System Interface (SCSI), USB or the like, for connecting expansion cards, drives and other subsystems as well as other buses, such a front side bus (FSB), which connects processor 470 to software system.

Optionally, operator and administrative interfaces, e.g., a display, keyboard, and a cursor control device, may also be coupled to bus 420 to support direct operator interaction with a computer system. Other operator and administrative interfaces can be provided through network connections connected through communication port 460. The external storage device 410 can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprise” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc. The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

While the foregoing describes various embodiments of the invention, other and further embodiments of the invention may be devised without departing from the basic scope thereof. The scope of the invention is determined by the claims that follow. The invention is not limited to the described embodiments, versions, or examples, which are included to enable a person having ordinary skill in the art to make and use the invention when combined with information and knowledge available to the person having ordinary skill in the art.

### Advantages of Invention

The present invention provides a coating apparatus for coating thin films on substrates.

The present invention provides a coating apparatus that optimizes a coating process for preparing uniform thin films on substrates.

The present invention provides a method for preparing uniform thin films on substrates.

We claim:

1. A thin film coating apparatus comprising:
a sample holder rotatably configured in the thin film coating apparatus, wherein the sample holder is coupled to a motor configured to rotate the sample holder;
a heating chamber disposed around the sample holder, wherein the heating chamber is configured to supply heat to a substrate loaded on the sample holder;
a top cover disposed on the heating chamber, the top cover configured to selectively allow access to the substrate loaded on the sample holder; and
a controller communicably coupled to the motor, the heating chamber, and the top cover, the controller comprising a processor communicably coupled to a memory storing instructions executable by the processor, the controller configured to:
detect a speed of rotation of the sample holder;
detect a temperature of the substrate loaded on the sample holder; and
operate the top cover to allow access to the substrate loaded on the sample holder when the detected speed of rotation of the sample holder, and the detected temperature of the substrate loaded on the sample holder are within corresponding predefined ranges.

2. The thin film coating apparatus of claim 1, wherein the controller is further configured to operate the motor to vary the speed of rotation of the sample holder from the predefined range to a second value after a predefined duration of time.

3. The thin film coating apparatus of claim 1, further comprising a vacuum chamber configured to apply a vacuum force at the sample holder to secure the substrate to the sample holder, wherein the controller is configured to:
detect a presence of the substrate on the sample holder; and
operate the vacuum chamber to apply a vacuum force at the sample holder to secure the substrate to the sample holder on positive detection of the presence of the substrate on the sample holder.

4. The thin film coating apparatus of claim 1, further comprising a touch screen device configured to at least one of display one or more operating parameters of the thin film coating apparatus and accept input relating to the one or more parameters of the thin film coating apparatus.

5. The thin film coating apparatus of claim 4, wherein the one or more operating parameters comprise at least one of a current speed of the sample holder, the predefined range for the speed of the sample holder, a temperature of the heating chamber, a state of the top cover, a duration of operation of the apparatus, and presence of the substrate loaded on the sample holder.

6. The thin film coating apparatus of claim 1, further comprising a hot plate communicably coupled to the controller, the controller configured to operate the hot plate to enable the hot plate to be maintained at a predefined temperature.

7. The thin film coating apparatus of claim 1, further comprising a solution pourer adapted to store a solution to be dispensed on the substrate loaded on the sample holder, the solution pourer communicably coupled to the controller, wherein the controller configured to operate the solution pourer to dispense a predefined quantity of the solution on the substrate loaded on the sample holder through the top cover.

8. The thin film coating apparatus of claim 8, wherein the solution pourer comprises one or more syringes adapted to store the solution, wherein the syringes are actuated to dispense the predefined quantity of the solution by one or more actuators, and wherein the one or more actuators are operable by the controller.

9. A method for use of the thin film coating apparatus of claim 1, the method comprising:
detecting, by the controller, the speed of rotation of the sample holder;
detecting, by the controller, the temperature of the substrate loaded on the sample holder; and
operating, by the controller, the top cover to allow access to the substrate loaded on the sample holder when the detected speed of rotation of the sample holder, and the temperature of the substrate loaded on the sample holder are within corresponding predefined ranges.

10. The method of claim 9, further comprising:
varying, by the controller, the speed of rotation of the sample holder from the predefined range to a second value after a predefined duration of time.
